(19) United States
(12) Patent Application Publication
(10) Pub. No.: US 2006/0157793 A1
(43) Pub. Date: Jul. 20, 2006

(54) MOS field effect transistor and manufacture method therefor

(75) Inventor: Masashi Shima, Kawasaki (JP)

Correspondence Address: WESTERMAN, HATTORI, DANIELS & ADRIAN, LLP, 1250 CONNECTICUT AVENUE, NW, SUITE 700, WASHINGTON, DC, 20036, US

(73) Assignee: FUJITSU LIMITED, Kawasaki (JP)

(21) Appl. No.: 11/117,612

(22) Filed: Apr. 29, 2005

(30) Foreign Application Priority Data
Jan. 20, 2005 (JP) 2005-12507

(51) Int. Cl. H01L 29/94

(52) U.S. Cl. 257/368

(57) ABSTRACT

A method of manufacturing an MOS field effect transistor which reduces a leak current between a source and a drain, thereby reducing power consumption in a standby mode, so that the power consumption can be reduced without impairing the fast operation of the transistor circuit. The method includes the steps of: forming a gate electrode on a semiconductor substrate via a gate insulating film; forming a gate-electrode sidewall on a side wall of the gate electrode; forming a source and a drain respectively on both sides of the gate-electrode sidewall; and forming an insulator overlying a pn junction region of the source and the drain.

### CROSS-REFERENCE TO RELATED APPLICATIONS

This application is based upon and claims the benefit of priority from the prior Japanese Patent Application No. 2005-12507, filed on Jan. 20, 2005, the entire contents of which are incorporated herein by reference.

### BACKGROUND OF THE INVENTION

1) Field of the Invention

The present invention relates to an MOS (Metal Oxide Semiconductor) field effect transistor having an insulator inside a silicon layer of a semiconductor substrate, and a method of manufacturing the MOS field effect transistor.

2) Description of the Related Art

For faster information processing and data communication and lower power consumption, there are demands for MOS field effect transistors with enhanced performances which ensures a faster operation with a low leak current. It is however known that miniaturization of the transistor structure increases a standby current when the gate voltage is 0 V, thereby increasing power consumption. Therefore, conventionally, the standby current when the transistor is off is decreased by suppressing the expansion of a depletion layer from a drain electrode by increasing channel impurity concentration and pocket impurity concentration.

This method however has a problem such that an increase in the channel impurity concentration increases the vertical electric field when the device is in operation, thereby lowering the mobility and thus reducing a drive current.

With regard to the depth of the junction of the source/drain regions, when the junction is deep, a parasitic resistance decreases, thus increasing the drive current, but a leak current increases, thus increasing power consumption, and also a junction leak increases, which hinders a fast operation.

Japanese Patent Application Laid-Open No. H7-130995 discloses a semiconductor device which has a high concentration impurity layer formed in a substrate at a channel portion and on both sides of a gate, without lying in source/drain regions, with a material of a low ion permeability selectively deposited or grown at the source/drain regions, and suppresses a punch through, thereby reducing the parasitic capacitance and the leak current.

Japanese Patent Application Laid-Open No. S64-28962 discloses a semiconductor device which includes an insulating film formed at a region deeper than a channel-forming region in a monocrystalline semiconductor layer under a gate electrode, in such a way as to block a punch-through current path between the source and the drain.

The method, however, suffers a probable variation in the leak current depending on the device since the insulating film is not formed self-aligned with the gate electrode.

### SUMMARY OF THE PRESENT INVENTION

In view of the above problems, it is an object of the present invention to provide a method of manufacturing an MOS field effect transistor which reduces a leak current between a source and a drain, thereby reducing power consumption in a standby mode, so that the power consumption can be reduced without impairing the fast operation of the transistor circuit.

It is another object of the present invention to provide an MOS field effect transistor, which is well matched with an existing process and is cost effective, without significantly changing the process steps, by using the manufacture method of an MOS field effect transistor.

In order to solve the above problems, the present invention has the following features.
1. A method of manufacturing an MOS field effect transistor according to the present invention comprises the steps of: forming a gate electrode on a semiconductor substrate via a gate insulating film; forming a gate-electrode sidewall on a side wall of the gate electrode; forming a source and a drain respectively on both sides of the gate-electrode sidewall; and forming an insulator overlying a pn junction region of the source and the drain.
2. An MOS field effect transistor according to the present invention comprises: a semiconductor substrate; a gate electrode formed on the semiconductor substrate via a gate insulating film; a gate-electrode sidewall formed on a side wall of the gate electrode; a source and a drain respectively formed on both sides of the gate-electrode sidewall; and an insulator overlying a pn junction region of the source and the drain.

### BRIEF DESCRIPTION OF THE DRAWINGS

FIG. 1 is a diagram showing the cross section of an MOS field effect transistor according to the present invention;

FIG. 2 is a diagram showing an insulating-film sidewall having a laminated structure;

FIGS. 3A to 3C are diagrams showing a manufacture process for an MOS field effect transistor according to a first embodiment, in which FIG. 3A shows a state in which a gate insulating film and a gate electrode are formed in a semiconductor substrate, FIG. 3B shows a state in which source/drain regions are etched, and FIG. 3C shows a state in which SiO₂ is formed on a side wall of the semiconductor substrate;

FIGS. 4D to 4F are diagrams showing the manufacture process for the MOS field effect transistor according to the first embodiment, in which FIG. 4D shows a state in which a sidewall is formed by etch back, FIG. 4E shows a state in which Si is deposited at the source/drain regions by CVD, and FIG. 4F shows a state in which a punch through stop, an extension, and source/drain regions are doped with impurities;

FIGS. 5G and 5H are diagrams showing the manufacture process for the MOS field effect transistor according to the first embodiment, in which FIG. 5G shows a state in which a contact etching stop film is formed, and FIG. 5H shows the cross section of the MOS field effect transistor according to the first embodiment;

FIGS. 6B, 6B′ and 6C are diagrams showing, as a second embodiment, a process different from the manufacture process for an MOS field effect transistor according to the first embodiment, in which FIG. 6B shows a state in which source/drain regions are etched, FIG. 6B′ shows a state in which a sidewall is removed, and FIG. 6C shows a state in which SiO₂ is formed at a gate electrode and the side wall of the semiconductor substrate; and

FIGS. 7C and 7C′ are diagrams showing, as a third embodiment, a process different from the manufacture processes for the MOS field effect transistor according to the first and the second embodiments, in which FIG. 7C shows a state in which SiO₂ is formed at a gate electrode and the side wall of the semiconductor substrate, and FIG. 7C′ shows a state in which SiN is deposited on SiO₂.

### DETAILED DESCRIPTION OF THE PREFERRED EMBODIMENTS

Exemplary embodiments of the present invention will be explained below with reference to the accompanying drawings. The following explanation is considered as illustrative only, and since variously changed and modified embodiments other than the one described can be made within the scope of the spirit of the appended claims by those skilled in the art, the embodiments do not limit the scope of the present invention.

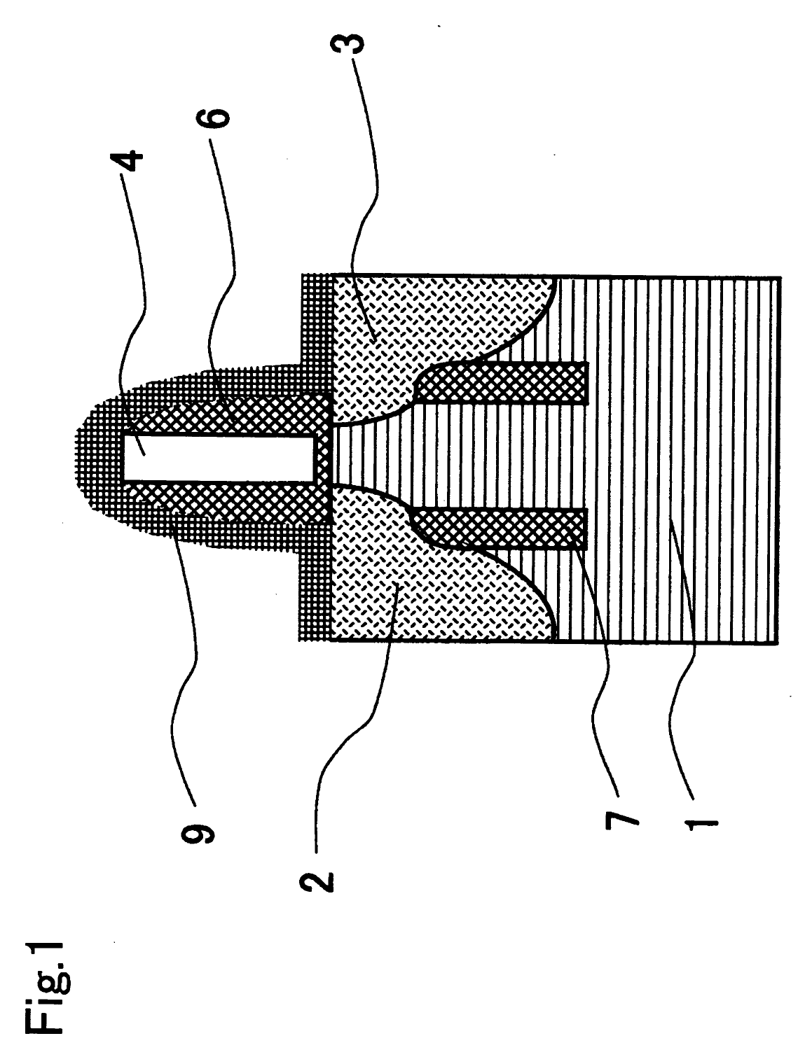

FIG. 1 is a diagram showing the cross section of the MOS field effect transistor according to the present invention. An insulator 7 is directly inserted and buried in such a way as to overlie a pn junction region between a source 2 and a drain 3, and a body 1. The insulator is formed in such a way as to be self-aligned with a gate-electrode sidewall 6. This directly cuts a leak current between the source and the drain, which is originated from the flow-out of an impurity from the source and the drain, thereby reducing power consumption and reducing the junction leak current and junction capacitance between the source and the drain, and the body. Accordingly, lower power consumption and a faster operation are achieved at the same time.

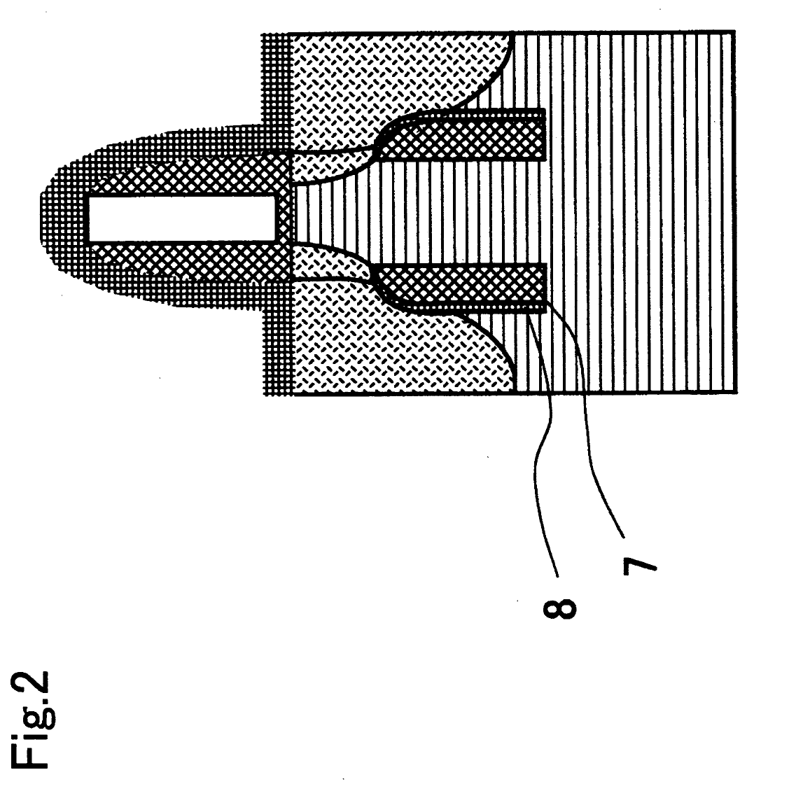

FIG. 2 is a diagram showing the insulator shown in FIG. 1 having a laminated structure. The laminated structure of the buried insulator including a silicon oxide film (SiO₂) 7 and a silicon nitride film (SiN) 8 can prevent the mobility of the transistor from dropping by stress on the buried insulator. Accordingly, it is possible to control stress which influences the channel region and improve the mobility.

### Embodiments

The present invention is further explained below with reference to embodiments, but the present invention is not limited by the embodiments.

### First Embodiment

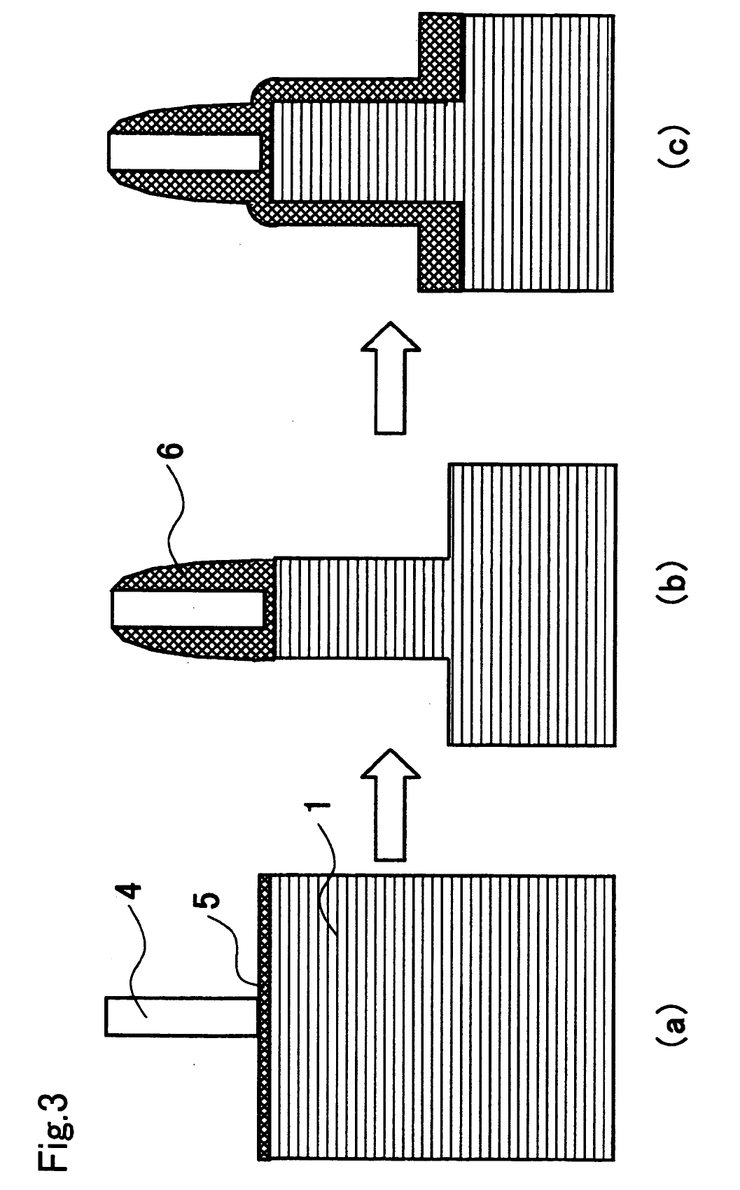

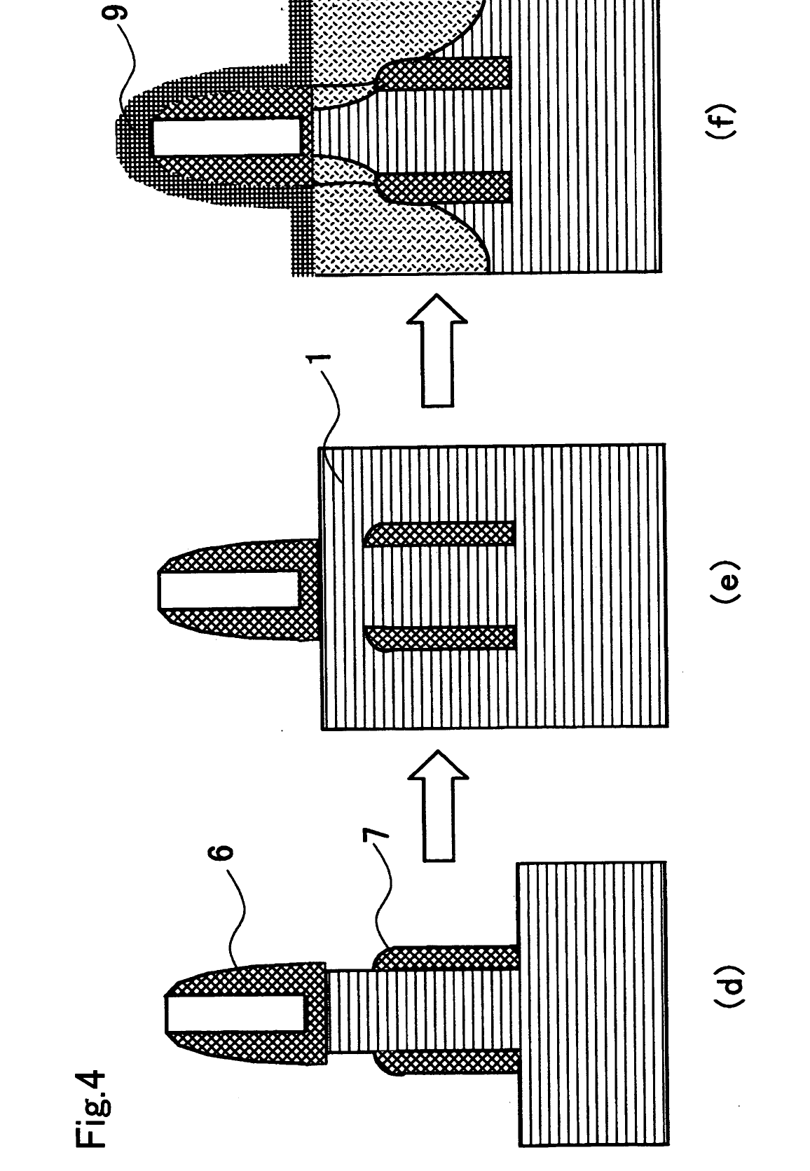

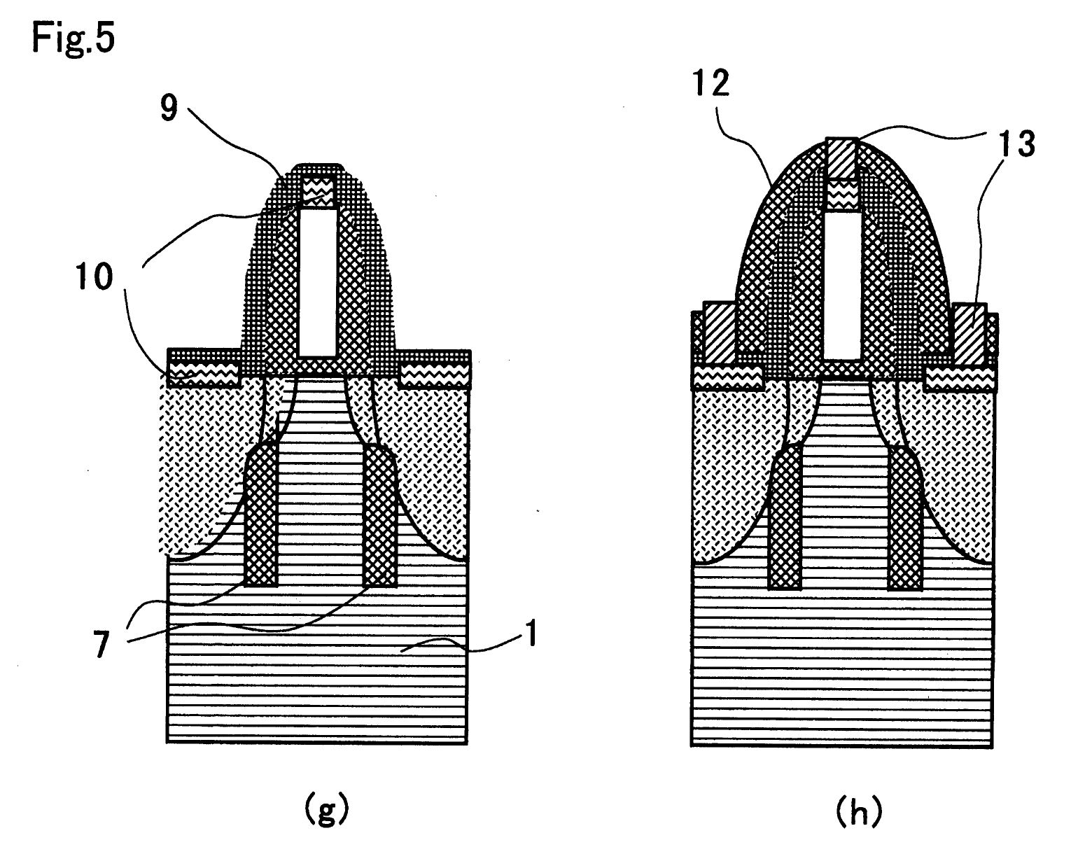

FIGS. 3A to 3C, FIGS. 4D to 4F, and FIGS. 5G and 5H are diagrams showing the manufacture process for an MOS field effect transistor according to a first embodiment. FIG. 3A shows a state in which a gate insulating film and a gate electrode are formed in a semiconductor substrate, FIG. 3B shows a state in which source/drain regions are etched, and FIG. 3C shows a state in which SiO₂ is formed on a side wall of the semiconductor substrate. FIG. 4D shows a state in which a gate-electrode sidewall and an insulator are formed by etch back, FIG. 4E shows a state in which silicon (Si) is deposited at the source/drain regions by CVD, and FIG. 4F shows a state in which a punch through stop, an extension, and source/drain regions are doped with impurities. FIG. 5G shows a state in which a contact etching stop film is formed, and FIG. 5H shows the cross section of the MOS field effect transistor according to the first embodiment.

As shown in FIGS. 3A to 3C, after a device isolation step in the manufacture process, a gate insulating film 5 of SiON and a gate electrode 4 of polysilicon are formed on a semiconductor substrate 1. In the embodiments to be described below, a silicon (Si) substrate is used as the semiconductor substrate. Next, a sidewall 6 of SiO₂ is formed on a gate side wall, after which source/drain regions are etched using the gate electrode 4 and the sidewall 6 as a mask. Then, SiO₂, for example, is formed on the side wall of the semiconductor substrate by thermal oxidization.

Next, as shown in FIGS. 4D to 4F, an insulator 7 is formed on the side walls of the etched source/drain regions by etch back. At this time, the side face of the insulator 7 which lays on the gate electrode 4 side is aligned with a region directly underlying the outer wall portion of the gate-electrode sidewall 6. The etch-over amount is adjusted in such a way that the height of the insulator 7 becomes lower than the height of the region where secondary electrons (or secondary holes) are formed when the transistor is on. Thereafter, Si is deposited at the source/drain regions by CVD, and the gate-electrode sidewall 6 once formed is removed by etching. Then, punch through stop and extension injection are performed, after which the gate-electrode sidewall 6 is formed again to dope an impurity in the source/drain regions. After injected ions are activated by activation annealing, NiSi, for example, is formed as a silicide 10, as shown in FIGS. 5G and 5H. An SiN film 9 having tensile stress, for example, is formed on the silicide as the contact etching stop film 9. Then, an interlayer insulating film 12 is formed, a contact hole is formed, and an electrode 13 is formed, thereby completing the MOS field effect transistor according to the first embodiment.

As the insulator 7 is directly inserted in such a way as to overlie the pn junction region between the source/drain regions 2 and 3 and the body region 1, the leak current between the source and the drain, which is originated from the flow-out of an impurity from the source and the drain, is directly cut. This reduces power consumption and the junction leak current and junction capacitance between the source and the drain, and the body, so that lower power consumption and a faster operation are achieved at the same time.

### Second Embodiment

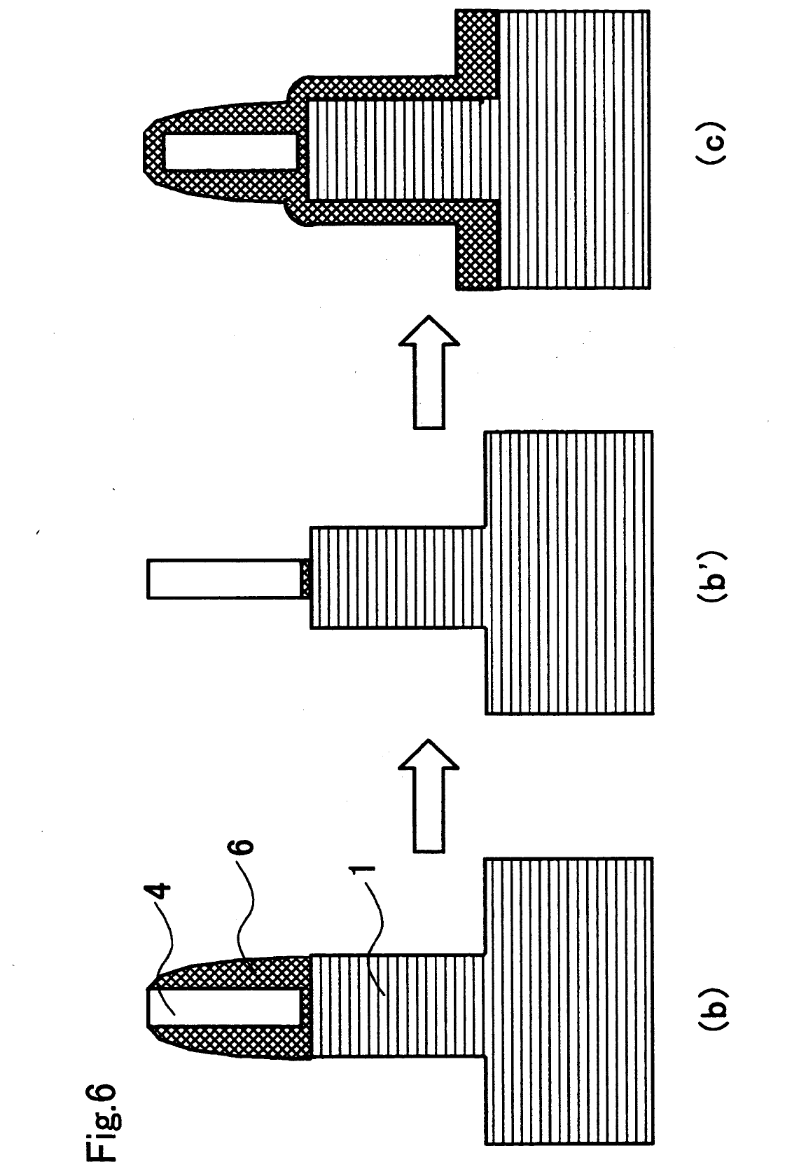

FIGS. 6B, 6B′, and 6C are diagrams showing, as a second embodiment, a process different from the manufacture process for an MOS field effect transistor according to the first embodiment.

FIG. 6B shows a state in which source/drain regions are etched, FIG. 6B′ shows a state in which a sidewall is removed, and FIG. 6C shows a state in which SiO₂ is formed at a gate electrode and the side wall of the semiconductor substrate.

After a device isolation step in the manufacture process, the gate insulating film 5 of SiON and the gate electrode 4 of polysilicon are formed on the semiconductor substrate as shown in FIG. 3A of the first embodiment. Next, the sidewall 6 is formed on a gate side wall, after which source/drain regions are etched using the gate electrode 4 and the sidewall 6 as a mask, as shown in FIG. 6B. Then, as shown in FIG. 6B′, the gate-electrode sidewall 6 is once removed. Then, a silicon oxide film (SiO₂), for example, is deposited on the side wall of the semiconductor substrate I and the side wall of the gate electrode 4 by CVD, as shown in FIG. 6C. The removal of the gate-electrode sidewall 6 can permit a silicon oxide film thinner than that of the first embodiment to be deposited on the side wall of the semiconductor substrate and the side wall of the gate electrode. The thickness of the silicon oxide film to be deposited is made thinner than that of the gate-electrode sidewall 6 before removal. Next, the insulator 7 is formed on the side walls of the etched source/drain regions by etch back as per the first embodiment. The height of the insulator 7 can be controlled in such a way as to become smaller than the height of the region where secondary electrons (or secondary holes) are formed when the transistor is on, by making the silicon oxide film to be deposited thinner than the gate-electrode sidewall 6 before removal.

Thereafter, Si is deposited at the source/drain regions by CVD, and the gate-electrode sidewall 6 is removed by etching. Then, punch through stop and extension injection are performed, after which the gate-electrode sidewall 6 is formed to dope an impurity in the source/drain regions. After injected ions are activated by activation annealing, NiSi, for example, is formed as the silicide 10. An SiN film having tensile stress, for example, is formed on the silicide as the contact etching stop film 9. Then, the interlayer insulating film 12 is formed, a contact hole is formed, and the electrode 13 is formed, thereby completing the MOS field effect transistor according to the second embodiment.

Through the process, the leak current between the source and the drain, which is originated from the flow-out of an impurity from the source and the drain, is directly cut, thereby reducing power consumption and the junction leak current and junction capacitance between the source and the drain, and the body, so that lower power consumption and a faster operation are achieved at the same time.

### Third Embodiment

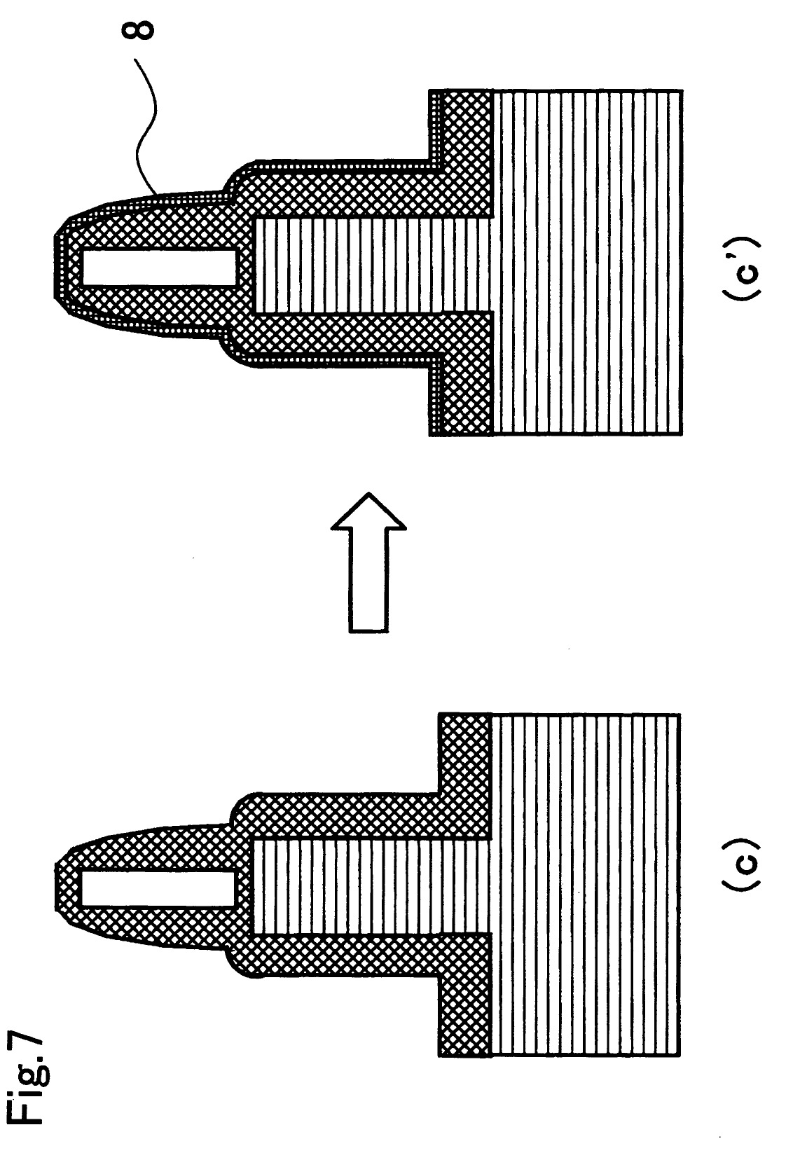

FIGS. 7C and 7C′ are diagrams showing, as a third embodiment, a process different from the manufacture process for the MOS field effect transistor according to the first and the second embodiments.

FIG. 7C shows a state in which SiO₂ is formed at a gate electrode and the side wall of the semiconductor substrate, and FIG. 7C′ shows a state in which SiN is deposited on SiO₂.

After a device isolation step in the manufacture process, the gate insulating film 5 of SiON and the gate electrode 4 of polysilicon are formed on the semiconductor substrate as shown in FIG. 3A of the first embodiment. Next, a sidewall is formed on a gate side wall, after which source/drain regions are etched using the gate electrode 4 and the sidewall 6 as a mask, as shown in FIG. 6B of the second embodiment. Then, as shown in FIG. 6B′, the gate-electrode sidewall 6 is once removed. Then, SiO₂, for example, is deposited on the side wall of the semiconductor substrate 1 and the side wall of the gate electrode 4 by CVD, as shown in FIG. 7C. The thickness of the film to be deposited is made thinner than the thickness of the removed gate-electrode sidewall 6. Thereafter, SiN, for example, is deposited on SiO₂ by CVD, thereby providing an SiO₂/SiN laminated structure as shown in FIG. 7C′.

Next, the insulator 7 having the SiO₂/SiN laminated structure which can control stress that influences the channel region is formed on the side walls of the etched source/drain regions by etch back. The height of the insulator 7 can be controlled in such a way as to become smaller than the height of the region where secondary electrons (or secondary holes) are formed when the transistor is on, by adjusting the etch-over amount. Thereafter, Si is deposited at the source/drain regions by CVD, and the gate-electrode sidewall 6 is removed by etching. Then, punch through stop and extension injection are performed, after which the gate-electrode sidewall 6 is formed to dope an impurity in the source/drain regions. After injected ions are activated by activation annealing, NiSi, for example, is formed as the silicide 10. An SiN film having tensile stress, for example, is formed on the silicide as the contact etching stop film 9. Then, the interlayer insulating film 12 is formed, a contact hole is formed, and the electrode 13 is formed, thereby completing the MOS field effect transistor according to the third embodiment.

According to the third embodiment, the SiO₂/SiN laminated structure of the insulator 7 can prevent reduction in the mobility of the transistor by the stress on the insulator 7, thus making it possible to control the stress that influences the channel region and improve the mobility.

The method of manufacturing an MOS field effect transistor according to the present invention reduce a leak current between a source and a drain, thereby reducing power consumption in a standby mode, so that the power consumption can be reduced without impairing the fast operation of the transistor circuit.

The use of the manufacture method can provide an MOS field effect transistor, which is well matched with an existing process and is cost effective, without significantly changing the process steps.

1. A method of manufacturing an MOS field effect transistor, comprising the steps of:
forming a gate electrode on a semiconductor substrate via a gate insulating film;
forming a gate-electrode sidewall on a side wall of the gate electrode;
forming a source and a drain respectively on both sides of the gate-electrode sidewall; and
forming an insulator overlying a pn junction region of the source and the drain.

2. The method of manufacturing an MOS field effect transistor according to claim 1, wherein the insulator is formed self-aligned with the gate-electrode sidewall.

3. The method of manufacturing an MOS field effect transistor according to claim 1, wherein the insulator is formed below an inversion layer generated when a gate bias is applied to the gate electrode.

4. The method of manufacturing an MOS field effect transistor according to any one of claims 1, 2 and 3, wherein the insulator is a laminated film comprising a silicon oxide film and a silicon nitride film.

5. The method of manufacturing an MOS field effect transistor according to any one of claims 1, 2 and 3, further comprising the steps of:
etching source/drain regions in such a manner as to be self-aligned with the gate-electrode sidewall;
depositing an insulating film in such a way as to cover the gate-electrode sidewall; and
selectively growing silicon on the semiconductor substrate.

6. An MOS field effect transistor comprising:
a semiconductor substrate;
a gate electrode formed on the semiconductor substrate via a gate insulating film;
a gate-electrode sidewall formed on a side wall of the gate electrode;
a source and a drain respectively formed on both sides of the gate-electrode sidewall; and
an insulator overlying a pn junction region of the source and the drain.

7. The MOS field effect transistor according to claim 6, wherein the side face on the gate electrode side of the insulator is aligned with a region directly underlying the end portion of the outer wall of the gate-electrode sidewall.

8. The MOS field effect transistor according to claim 6, wherein the insulator is formed below the region of an inversion layer generated when a gate bias is applied to the gate electrode.

9. The MOS field effect transistor according to any one of claims 6, 7 and 8, wherein the insulator is a laminated film comprising a silicon oxide film and a silicon nitride film.

10. The MOS field effect transistor according to any one of claims 6, 7 and 8, wherein each of the source and the drain comprises a silicon film selectively grown on the semiconductor substrate.
